(19) United States
(12) Patent Application Publication
(10) Pub. No.: US 2005/0156678 A1
(43) Pub. Date: Jul. 21, 2005

(54) Voltage control oscillator

(76) Inventor: Chao-Hsin Lu, Dayuan Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/930,234

(22) Filed: Aug. 31, 2004

(30) Foreign Application Priority Data
Oct. 14, 2003 (TW) 092128481

(51) Int. Cl. H03B 1/00

(52) U.S. Cl. 331/57

(57) ABSTRACT

A voltage control oscillator includes a regulator and several voltage controlled delay cells. The regulator receives a control voltage and outputs an operation voltage. The voltage controlled delay cells are coupled to each other in serial to form a feedback circuit for outputting a clock signal. The delay cell includes a first inverter, a second inverter, and a cross latch. The first inverter receives a first input signal and outputs a first output signal, and the second inverter receives a second input signal and outputs a second output signal. The cross latch is used for latching the first output signal and the second output signal.

This application claims the benefit of Taiwan application Serial No. 92128481, filed Oct. 14, 2003, the subject matter of which is incorporated herein by reference.

### BACKGROUND OF THE INVENTION

1. Field of the Invention

The invention relates in general to a voltage control oscillator (VCO), and more particularly to a VCO, which includes voltage control delay cells formed by using inverters.

2. Description of the Related Art

The phase locked loop (PLL), a feedback circuit widely applied in the scientific fields such as electronics and electrical engineering, is used to generate signals having a specific frequency for a signal modulation/demodulation circuit in a communication system, a clock generator, a motor control circuit, a clock synchronization circuit in the PC memory or interface bus, or a frequency signal generator.

Referring to FIG. 1A, a block diagram of a conventional PLL is shown. The PLL 100 includes a phase frequency detector (PFD) 110, a charge pump (CP) 120, a loop filter (LF) 130, a VCO 140, and a divider 150.

Referring to FIG. 1B, a block diagram of a conventional VCO 140 is shown. The VCO 140 includes a replica bias unit 142 and several voltage control delay cell (or called voltage control delay line, VCDL) 144, which are coupled to each other in serial to form a feedback circuit. The replica bias unit 142 is input by a control voltage Vc and outputs a voltage Vb. The voltages Vb and Vc respectively provide a high voltage level VH and a low voltage level VL for the VCDL 144. By using the replica bias unit 142, the noise coupled to the input control voltage Vc can be reduced.

Referring to FIG. 1C, a circuit diagram of the conventional VCDL 144 is shown. The VCDL 144, a differential delay cell, includes transistors M1 to M7, and has a positive input terminal ‘ip’ and a negative input terminal ‘in’ respectively coupled to the gate electrodes of the transistors M1 and M2, a positive output terminal ‘op’ and a negative output terminal ‘on’ respectively coupled to the drain electrodes of the transistors M2 and M1. The source electrodes of the transistors M1 and M2 are coupled to the drain electrode of the transistor M3, and the gate electrode and the source electrode of the transistor M3 are respectively coupled to the voltage Vb and the system voltage VDD. In addition, the transistors M4, M6 and the transistors M5, M7, forming symmetric loading circuits, are respectively coupled to the drain electrodes of the transistors M1 and M2. The control voltage Vc is input to the gate electrodes of the transistors M6 and M7.

As mentioned above, the required operation voltage (VH-VL) has to be at least larger than the sum of the threshold voltages of the transistors M1 and M6 or the transistors M2 and M7, and less than the sum of the saturation voltage VDS3 of the transistor M3 and the operation voltage of the transistor M1. Therefore, the required system operation voltage must be high, and the VCO 140 formed by current differentials has less sensitivity to the noise, and has small linear active region. Moreover, the gate delay controls by using the voltage Vc to control the loading resistors require a complicated circuit structure including several transistors, so the conventional VCO occupies a large circuit area and requires a high production cost.

### SUMMARY OF THE INVENTION

It is therefore an object of the invention to provide a VCO including at least a delay cell. The delay cell includes a first inverter, a second inverter, and a cross latch. The VCO has low power consumption, small area occupation, and high transmission rate.

It is another object of the invention to provide a voltage control delay cell, used in a VCO. The voltage control delay cell includes a first inverter, a second inverter, and a cross latch. The delay cell has low power consumption, small area occupation, high transmission rate, and low sensitivity to the noise.

It is another object of the invention to provide a VCO including a regulator and at least a delay cell. The delay cell includes a first inverter, a second inverter, and a cross latch. By using the regulator, the sensitivity of the VCO to the noise can be reduced. The VCO has low power consumption, small area occupation, high transmission rate, and low sensitivity to the noise.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a block diagram of a conventional PLL;

FIG. 1B is a block diagram of a conventional VCO;

FIG. 1C is a circuit diagram of the conventional VCDL;

FIG. 2A is a schematic diagram of the VCO according to a preferred embodiment of the invention;

FIG. 2B is another circuit diagram of the VCO according to a preferred embodiment of the invention;

FIG. 3A is a circuit diagram of the delay cell in FIG. 2A or FIG. 2B;

FIG. 3B is a circuit diagram of another delay cell in FIG. 2A or FIG. 2B; and

FIG. 3C is a circuit diagram of a third delay cell in FIG. 2A or FIG. 2B.

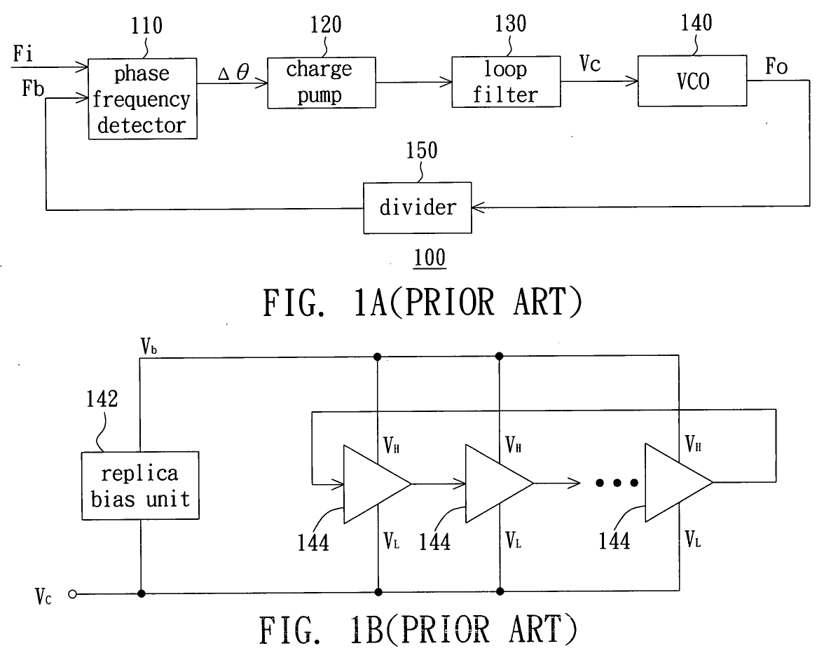

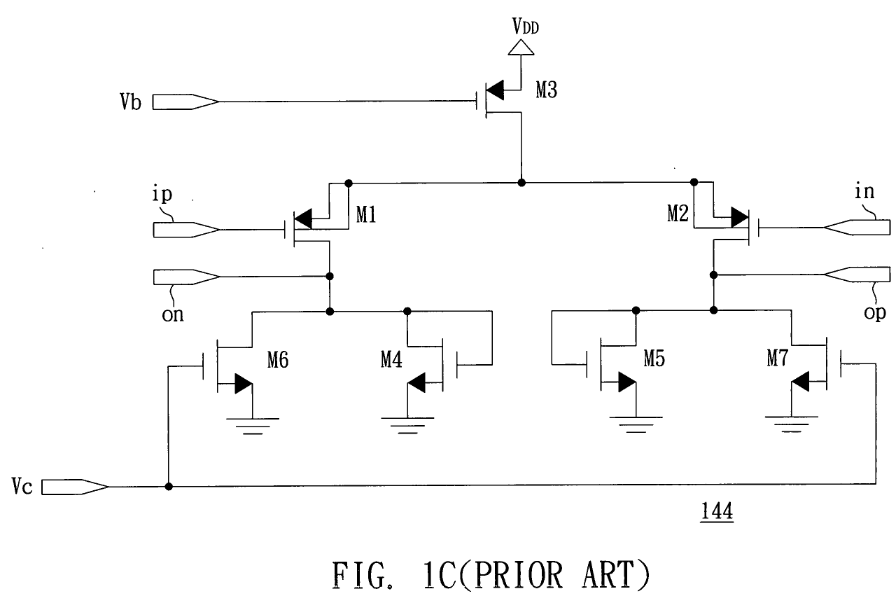

### DETAILED DESCRIPTION OF THE INVENTION

The VCO in the invention uses a cross latch to symmetrically couple with two simple-structured inverters. Therefore, the operation voltage and area occupation of the VCO can be reduced. The VCO can be applied to a phase locked loop (PLL) and a delay locked loop (DLL).

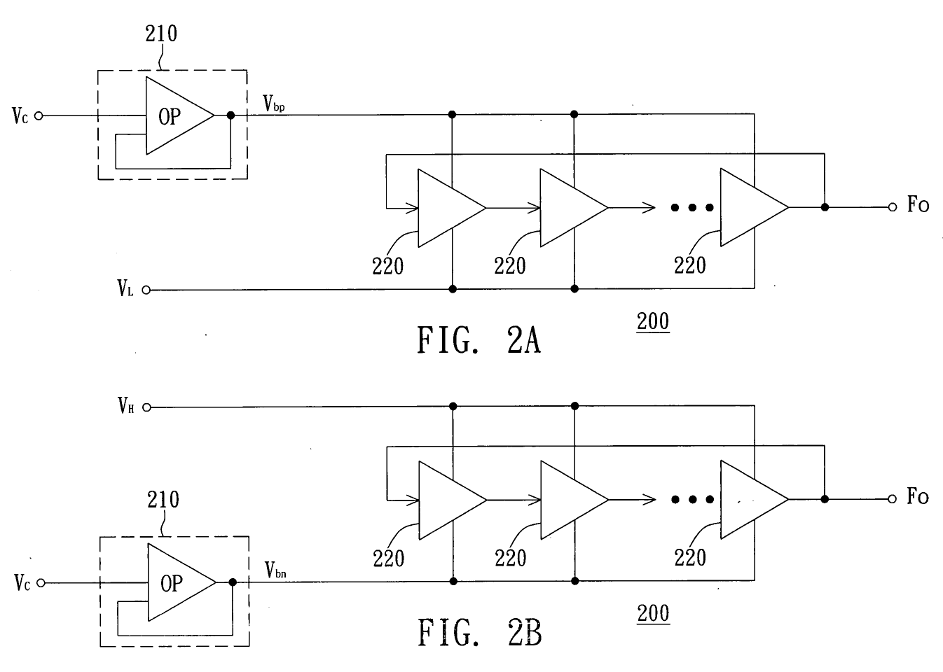

Referring to FIG. 2A, a schematic diagram of the VCO according to a preferred embodiment of the invention is shown. The VCO 200 outputs a clock signal Fo according to a control voltage Vc. The VCO 200 includes a regulator 210 and several delay cells 220. The regulator 210 outputs a bias voltage Vbp according to the control voltage Vc, which can lower the sensitivity of the voltage Vbp to the noise. The bias voltage Vbp is used as a common high voltage level VH of the delay cells. The delay cells are coupled to each other in serial to form a feedback circuit, and coupled to a common low voltage level VL. By using the LF 130 mentioned above to connect with the VCO 200, the sensitivity of the GND terminals of the delay cells to the voltage VL can be reduced, or the sensitivity of the VDD terminals of the delay cells to the voltage VH can be reduced, too. The regulator 210 can be an operational amplifier.

In the VCO circuit of the invention, the regulator input by the control voltage Vc can also output a bias voltage Vbn to be a common low voltage level VL of the delay cells, which are coupled to each other in serial to form a feedback circuit, as shown in FIG. 2B. In addition, the delay cells have a common high voltage level VH. The regulator 210 can lower the sensitivity of the GND terminal of the delay cells to the voltage VL, and the LF 130, coupled to the VCO 200, can help to reduce the sensitivity of the voltage VH or VL to the noise.

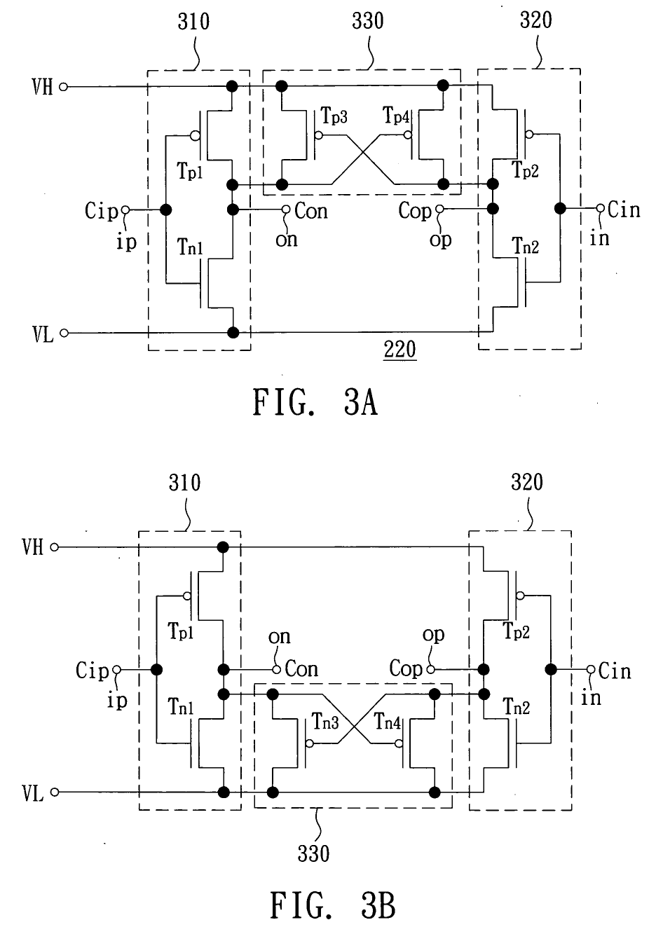

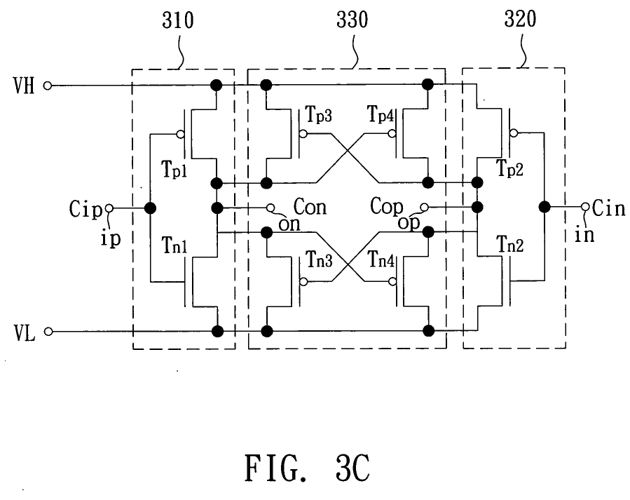

Referring to FIG. 3A, a circuit diagram of the delay cell 220 in FIG. 2A or FIG. 2B is shown. The delay cell 220 includes a first inverter 310, a second inverter 320, and a cross latch 330. The first inverter 310 includes a p-typed metal oxide semiconductor (PMOS) Tp1 and an n-typed metal oxide semiconductor (NMOS) Tn1. The second inverter 320 includes a PMOS Tp2 and a NMOS Tn2, and the cross latch 330 includes two PMOSs Tp3 and Tp4. The first inverter 310 includes an input terminal ‘ip’ for receiving an input signal Cip, and an output terminal ‘on’ for outputting an output signal Con. The frequency of the output signal Con is corresponding to the operation voltage VH or VL of the delay cell 220. The second inverter 320 includes an input terminal ‘in’ for receiving an input signal Cin, and an output terminal ‘op’ for outputting an output signal Cop. The first inverter 310 and the second inverter 320 are coupled to the common high voltage level VH and the low voltage level VL. In the cross latch 330, the drain electrode of the transistor Tp3 is coupled to the gate electrode of the transistor Tp4 for receiving the output signal Con while the drain electrode of the transistor Tp4 is coupled to the gate electrode of the transistor Tp3 for receiving the output signal Cop. The source electrodes of the transistors Tp3 and Tp4 are coupled to the high voltage level VH.

When the input signals Cip and Cin are respectively at a high voltage level (1) and at a low voltage level (0), the output signal Con of the first inverter 310 is at the low voltage level, and the output signal Cop of the second inverter 320 is at the high voltage level. The signal Con is further input to the gate electrode of the transistor Tp4 to turn the transistor Tp4 on and lift the voltage of the output terminal op to a high level. The signal Cop is further input to the gate electrode of the transistor Tp3 to turn the transistor Tp3 off. On the contrary, when the input signals Cip and Cin are respectively at a low voltage level and at a high voltage level, according to the same reason described above, the transistor Tp4 will be turned off and the transistor Tp3 will be turned on. Therefore, the cross latch 330 can speed up the transformation of the voltage levels, shorten the delay time of every delay cell, and thus increase the output frequency. Moreover, the cross latch design can provide the similar differential effect to reduce the sensitivity of the VCO to the noise. The output signals Con and Cop of one of the delay cells 220 in serial are respectively used to be the input signals Cip and Cin of the next delay cell 220 to form the feedback circuit mentioned above, in which the clock signal Fo is output. The clock signal Fo is the output signal Con of one of the delay cells 220.

FIG. 3B shows a circuit diagram of another delay cell 220. The cross latch 330 in FIG. 3B consists of two NMOSs Tn3 and Tn4. The drain electrode of the transistor Tn3 is coupled to the gate electrode of the transistor Tn4 for receiving the output signal Con while the drain electrode of the transistor Tn4 coupled to the gate electrode of the transistor Tn3 for receiving the output signal Cop. The source electrodes of the transistors Tn3 and Tn4 are coupled to the common low voltage level VL.

FIG. 3C shows a circuit diagram of a third delay cell 220. The cross latch 330 in FIG. 3C consists of two PMOSs and two NMOSs. The coupling of the two PMOSs Tp3 and Tp4 is the same as that in FIG. 3A and the coupling of the two NMOSs Tn3 and Tn4 is the same as that in FIG. 3B. The cross latch 330 can be even designed to be a more complicated circuit. Any other VCO design will be not departed from the skill scope of the invention as long as its cross latch can provide the similar differential effect to reduce the sensitivity of the VCO to the noise and speed up the transformation of the voltage levels.

The delay cell 220 in the invention controls the on-state resistance (Ron) of the transistors Tn1 and Tn2 or the transistors Tp1 and Tp2 by adjusting the difference value (VH-VL) of the high voltage level and the low voltage level, thereby changing the frequency of the output clock signal Fo. Furthermore, the inverter 310 or 320 used in the delay cell 220 has only two transistors, and if one is turned on, the other is turned off. Therefore, as long as the operation voltage (VH-VL) of the delay cell 220 is large than the maximum of the voltages Vtn and -Vtp, the required clock signal Fo can be generated, wherein the voltage Vtn represents the threshold voltage of the transistor Tn1 or Tn2, and the voltage Vtp represents the threshold voltage of the transistor Tp1 or Tp2. Therefore, the VCO 200 in the invention can be operated at a low operation voltage.

The cross latch 330 mentioned above is coupled to the first inverter 310 and the second inverter 320, so the delay cell 220, having the differential effect similar to a differential pair, can receive the differential signals Cip and Cin, and output a stable differential signals Con and Cop, and thus the delay cell has a larger linear active region. By the design of the inverters 310 and 320, the generated clock signal is close to a square wave. That is, the rising time and the falling time of the clock signal are relatively small. The sensitivity of the delay cell to the noise can be thus reduced and since the transformation rate of the square wave from the low level VL to the high level is very high, the noise coupled by the clock signal itself is also small.

As described above, the VCO of the invention has the following advantages:

1. The delay cell of the VCO in the invention is formed by the inverters having simple logical circuits, so the VCO has small area occupation, low power consumption, and spends the least gate delay time.

2. The VCO designed by using the inverters can generate the required clock signal as long as its operation voltage is large than the maximum of the voltages Vtn and -Vtp, that is, the maximum of the threshold voltages of two transistors in the inverter. Therefore, the operation voltage of the VCO can be reduced.

3. Since the clock signal generated by the inverters is close to a square wave, the VCO can have advantages of low sensitivity to the noise, and low noise generated by itself. The regulator can further reduce the noise coupled to the input signal of the VCO.

4. The cross latch designed in the delay cell is used for latching and speeding up the transformation of the voltage levels, shortening the delay time in every delay cell, and thus increase the resolution (frequency) of the output signal. Moreover, the cross latch can provide the similar differential effect to lower the sensitivity of the VCO to the noise. Meanwhile, the required operation voltage can be reduced and the VCO of the invention can have larger linear active region.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A voltage control oscillator (VCO), comprising:
a regulator, for receiving a control voltage and outputting an operation voltage; and
a plurality of delay cells, coupled to each other in serial to form a feedback circuit, for outputting a clock signal according to the operation voltage, one of the delay cells comprising:
a first inverter, for outputting a first inverted signal according to a first signal;
a second inverter, for outputting a second inverted signal according to a second signal; and
a cross latch, coupled to the first inverter and the second inverter, for latching the first inverted signal and the second inverted signal.

2. The VCO of claim 1, wherein the first inverted signal and the second inverted signal of the delay cell are input to the next delay cell in connection.

3. The VCO of claim 1, wherein the regulator is an operational amplifier.

4. The VCO of claim 1, wherein the cross latch comprises a first transistor and a second transistor, the drain of the first transistor is coupled to the gate of the second transistor and the output terminal of the first inverter, the drain of the second transistor is coupled to the gate of the first transistor and the output terminal of the second inverter.

5. The VCO of claim 4, wherein the sources of the first transistor and the second transistor are used for receiving the operation voltage.

6. The VCO of claim 4, wherein the cross latch further comprises a third transistor, and a fourth transistor, the drain of the third transistor is coupled to the gate of the fourth transistor and the output terminal of the first inverter, and the drain of the fourth transistor is coupled to the gate of the third transistor and the output terminal of the second inverter.

7. The VCO of claim 6, wherein sources of the first transistor and the second transistor are coupled to the operation voltage.

8. The VCO of claim 6, wherein the sources of the third transistor and the fourth transistor are coupled to the operation voltage.

9. The VCO of claim 6, wherein the first transistor and the second transistor are p-typed metal oxide semiconductors (PMOSs), and the third transistor and the fourth transistor are n-typed metal oxide semiconductors (NMOSs).

10. The VCO of claim 1, wherein the operation voltage is at a high voltage level or at a low voltage level.

11. The VCO of claim 1, wherein the first inverted signal is close to a square wave.

12. The VCO of claim 1, wherein the clock signal is the first inverted signal.

13. A delay cell, used in a VCO, the delay cell comprising:
a first inverter, for outputting a first inverted signal according to a first signal;
a second inverter, for outputting a second inverted signal according to a second signal; and
a cross latch, coupled to the first inverter and the second inverter, for latching the first inverted signal and the second inverted signal.

14. The delay cell of claim 13, wherein the cross latch comprises a first transistor and a second transistor, the drain of the first transistor is coupled to the gate of the second transistor and the output terminal of the first inverter, the drain of the second transistor is coupled to the gate of the first transistor and the output terminal of the second inverter.

15. The delay cell of claim 14, wherein the cross latch further comprises a third transistor, and a fourth transistor, the drain of the third transistor is coupled to the gate of the fourth transistor and the output terminal of the first inverter, and the drain of the fourth transistor is coupled to the gate of the third transistor and the output terminal of the second inverter.

16. The delay cell of claim 15, wherein the first transistor and the second transistor are PMOSs, and the third transistor and the fourth transistor are NMOSs.

17. The delay cell of claim 13, wherein the voltage control oscillator comprised a plurality of delay cells coupled to each other in serial.

18. The delay cell of claim 13, wherein a frequency of the first inverted signal is corresponding to an operation voltage of the delay cell.

19. The delay cell of claim 13, wherein the first inverted signal is close to a square wave.
